(19) United States
(12) Patent Application Publication
(10) Pub. No.: US 2025/0024630 A1
(43) Pub. Date: Jan. 16, 2025

(54) PARALELL HEAT EXCHANGER FOR DATA CENTER COOLING

(71) Applicant: Nortek Air Solutions Canada, Inc., Saskatoon (CA)

(72) Inventors: Gaoming Ge, Saskatoon (CA); Manfred Gerber, Saskatoon (CA)

(21) Appl. No.: 18/713,399

(22) PCT Filed: Nov. 24, 2021
(86) PCT No.: PCT/CA2021/051672

§ 371 Date: May 24, 2024

(51) Int. Cl. H05K 7/20

(52) U.S. Cl. CPC H05K 7/20145; H05K 7/20263; H05K 7/20781

(57) ABSTRACT

A conditioning system can include a first plenum to direct a first air, a second plenum to direct a second air stream in parallel with the first air stream directed through the first plenum, a first cooling component inside the first plenum and to cool the first air stream, a liquid to air heat exchanger (LAHX) inside the first plenum and downstream the first cooling component, the LAHX being fluidly connected to a rack cooling liquid circuit to cool the same using the first air stream, and a second cooling component arranged inside the second plenum and configured to cool the second air stream. The rack cooling liquid circuit can provide liquid cooling to one or more electronic components arranged inside the second plenum downstream of the second cooling component. The second air stream cooled by the second cooling component can sensibly cool the one or more electronic components.

### BACKGROUND

There are many applications where cooling is critical, such as data centers. A data center usually consists of several servers working continuously (24 hours per day, 7 days per week). The rapid growth of internet services is creating an increasingly high demand for computing and storage power from servers in data centers. While the performance of servers is improving, the power consumption of servers is also rising despite efforts in low power design of integrated circuits.

Servers are typically placed in racks in a data center. A data center requires maintenance of acceptable temperatures and humidity for reliable operation of the servers, which typically have cooling fans that draw air through the chassis for cooling. Server racks use electrical energy and produce heat as a byproduct of electrical resistance. The heat collectively generated by densely populated racks can have an adverse effect on the performance and reliability of the equipment in the racks if the heat is not adequately removed from the system. Accordingly, heating, ventilation, air conditioning (HVAC) systems are often an important part of the design of an efficient and robust data center.

In a data center room, server racks are typically laid out in rows with alternating cold and hot aisles between them. Such an orientation creates a front-to-back airflow pattern that draws conditioned air in from the cold aisles, located in front of the rack, and ejects heat out through the hot aisles behind the racks. Computer room air conditioner (CRAC) units are used in a data center to supply direct air cooling to the server racks. For example, in a data center room with hot and cold aisle configuration, hot air is moved out of the hot aisles and circulated as return air to the CRAC units. The CRAC units cool the air and supply the cooled air, e.g., via plenum, to the cold aisles. To achieve a sufficient air flow rate, hundreds of powerful CRAC units may be installed throughout a typical data center.

More recently, data centers have incorporated even more high-power density server racks, packing more high-density chips more compactly together to provide higher processing power. This is, e.g., due to the development of Artificial Intelligence (AI) and cloud-based services, which require high performance and high-power density processors such as control processing units (CPUs) and graphics processing units (GPUs). Cooling these high-density racks by maintaining a suitable thermal environment may not be possible with direct air cooling alone, such as direct air cooling of the racks by the CRAC units. For example, while a CRAC unit may maintain the thermal environment of a more conventional (or lower density) rack, the unit may not be able to effectively cool a high-power density rack because they may generate heat loads at a higher rate due to the higher density of electronics. In some cases, liquid cooling is additionally supplied to select components of the server to mitigate higher server heat loads. Such a hybrid cooling approach, utilizing liquid cooling for certain system components to supplement direct air cooling of the racks, can be used in a data center such as to provide adequate cooling of high-density racks without the need to completely overhaul existing infrastructure from a conventional data center.

### SUMMARY

The present application relates to systems and methods for providing cooling to a heat load, e.g., one or more electronic components in a data center. More particularly, the present application relates to systems and methods for providing hybrid cooling using parallel and independent air and liquid cooling to cool a heat load.

In at least some so-called hybrid cooling of server racks in a data center, computer room air conditioner (CRAC) units generate cool air that circulates through and cools electronic components disposed in rows of racks and also cools a liquid circulating through a second cooling device/system that supplies liquid cooling to the electronic components. In other words, in such hybrid systems, the CRAC or a number of CRACs condition air that is used to air-cool the electronic components and is used to cool a liquid that liquid-cools the components. The physical arrangement of such systems is commonly in series, in which the cooled air from the CRAC(s) circulates first through/around the electronic components, exiting in at a warmer temperature to then circulate through the second cooling device/system that provides liquid cooling to the electronic components.

In such data center applications, the second, liquid cooling device/system is commonly referred to as a rear-door heat exchanger. For example, a RDHX, which can be a liquid-to-air heat exchanger (LAHX) is located in the data center near an electronics rack including multiple electronic components. The RDHX uses air to cool a cooling liquid which is supplied to internal active components, e.g., processor(s) in the rack for liquid cooling thereof. The cooling load to cool the liquid in the RDHX can be less than the cooling load to air-cool the electronic components, because liquid cooling is generally more efficient and can remove more heat than air cooling. One approach is to use an RDHX placed in the airflow outlet of each electronics rack, e.g., in a hot aisle on the back or rear side of a row of server racks. Such an approach uses the CRAC unit to supply cooled air first to the rack and then to the RDHX in series. Here, the server racks reject heat into the air from the CRAC unit, and the heated air then is used to cool the liquid in the RDHX. One challenge with this approach, however, is despite the lower cooling requirement of the RDHX, this system may require excess cooling to be supplied directly to the rack in order to adequately cool the downstream RDHX.

Examples according to this disclosure include hybrid cooling systems in which air cooling and liquid cooling of the heat load (e.g., electronic components in a rack in a data center) is done in parallel. In an example, air, which can be return air, outdoor air, or a mixture of return and outdoor air is cooled by one or more CRACs and is directed along parallel air and liquid cooling paths of the system. For example, air is split between a first CRAC and a second CRAC (or a first set of CRACs and a second set of CRACs). The first CRAC cools a first air stream to a first temperature, which is then directed through a liquid cooling component (e.g., LAHX) to cool a liquid. The liquid circulating through the liquid cooling component rejects heat into the first air stream, which can be recirculated back into or exhausted out of the system. The cooled liquid is transported to and provides liquid cooling to the heat load. The second CRAC cools a second air stream to a second temperature, parallel to the cooling of the first air stream by the first CRAC, and the cooled second air stream is directed and provides air cooling to the heat load. The second air stream can then be recirculated back into or exhausted out of the system.

In some examples, the first temperature of the cooled first air stream is greater than the second temperature of the cooled second air stream. Such independent temperature control of each respective air stream can allow for an increased efficiency of cooling supplied to the servers in a data center and can enable hybrid cooling of data centers using less energy or water consumption than conventional systems. Additionally, in some examples, an evaporative cooling system is employed to supply a cooled liquid to and used by one or both of the first and second CRACs to cool the first and/or second air stream.

As noted, example conditioning systems according to this disclosure can include an evaporative cooling system to evaporatively cool a liquid, e.g., water using scavenger air. The cooled liquid from the evaporative cooling system can be supplied the CRAC(s), which can use the cooled liquid to cool air. In some applications and configurations of example systems, including an evaporative cooling system to help supply cooling to the CRAC(s) can reduce the water consumption in comparison with other approaches including, e.g. water chillers and may reduce the operating cost of the data center.

In an example, the evaporative cooling system can use an evaporative cooler and an LAHX, e.g., a dry coil disposed downstream of the evaporative cooler in a scavenger air plenum. The dry coil can also be configured to condition the cooling liquid using the scavenger air. In an example, the evaporative cooler and the dry coil are both operating. The cooling liquid is evaporatively cooled in the evaporative cooler and delivered to the CRAC(s). The cooling liquid that is delivered to and heated by the CRAC(s) is returned to a liquid inlet of the dry coil, which sensibly pre-cools the cooling liquid using the scavenger air exiting the evaporative cooler and delivers this pre-cooled liquid to a liquid inlet of the evaporative cooler.

Example evaporative cooling systems according to the present application can employ, inter alia, a Liquid-to-Air Membrane Energy Exchanger (LAMEE) as the evaporative cooler. Such systems employing a LAMEE may reduce cooling energy consumption compared to a system including a different type of evaporative cooler. Additionally, such cooling systems including a LAMEE may be significantly smaller in size and lighter compared to other direct evaporative coolers (DEC), including air-cooling DECs. Such systems may also reduce the water consumption in comparison with other systems including different types of evaporative coolers and may thereby reduce the operating cost of the data center. In some examples, systems described herein can reduce a maintenance requirement such as to help prevent biological growth as compared to some other evaporative coolers.

Example conditioning systems according to this disclosure may be operated in multiple modes. For example, the evaporative cooler can be bypassed (and in some cases deactivated completely) and the scavenger air can be channeled directly through the dry coil, because, e.g., the outdoor air conditions are such that the dry coil can carry the requirements to the CRAC(s) without the evaporative cooler.

In addition, or as an alternative to the evaporative cooling system, a chiller can be employed to provide a cooled liquid to the CRACs. The chiller can be a mechanical chiller, an absorption chiller, or a type of water-cooled chiller. The chiller can be the sole or primary source of cooling liquid supplied to the CRAC(s), or the chiller can be a source of supplementary cooling for the CRAC(s) in combination with an evaporative cooling system.

As described above, example parallel hybrid conditioning systems (PHCS) can include two independent air streams, one of which air cools a heat load and the other of which is supplied to a liquid cooling component to cool a liquid that is transported to, and liquid cools the heat load. The temperature of a first air stream supplied to the heat load, e.g., one or more electronic components can be less than the temperature of a second air stream supplied to the liquid cooling component. Also, the temperature of the first air stream supplied to the electronic components can be less than the temperature of the cooling liquid supplied for liquid cooling of the electronic components. In examples, the liquid cooling component, e.g., an LAHX uses the second air stream for liquid cooling of one or more active components in the electronic components, while passive components are directly cooled by the first air stream. The first and second air streams can flow through first and second plenums, respectively, and the first and second plenums can be fluidly isolated. The first and second plenums can be, e.g., ducts, space defined by raised floor panels, or space defined by a lowered ceiling.

This overview is intended to provide an overview of subject matter in the present application. It is not intended to provide an exclusive or exhaustive explanation of the invention. The detailed description is included to provide further information about the present application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present disclosure.

FIG. 1 schematically depicts an example parallel hybrid conditioning system in accordance with this disclosure.

FIG. 2 schematically depicts another example parallel hybrid conditioning system in accordance with this disclosure.

FIG. 3A schematically depicts another example parallel hybrid conditioning system in accordance with this disclosure.

FIG. 3B schematically depicts another example parallel hybrid conditioning system in accordance with this disclosure.

FIG. 3C schematically depicts another example parallel hybrid conditioning system in accordance with this disclosure.

And, FIG. 4 schematically depicts another example parallel hybrid conditioning system in accordance with this disclosure.

### DETAILED DESCRIPTION

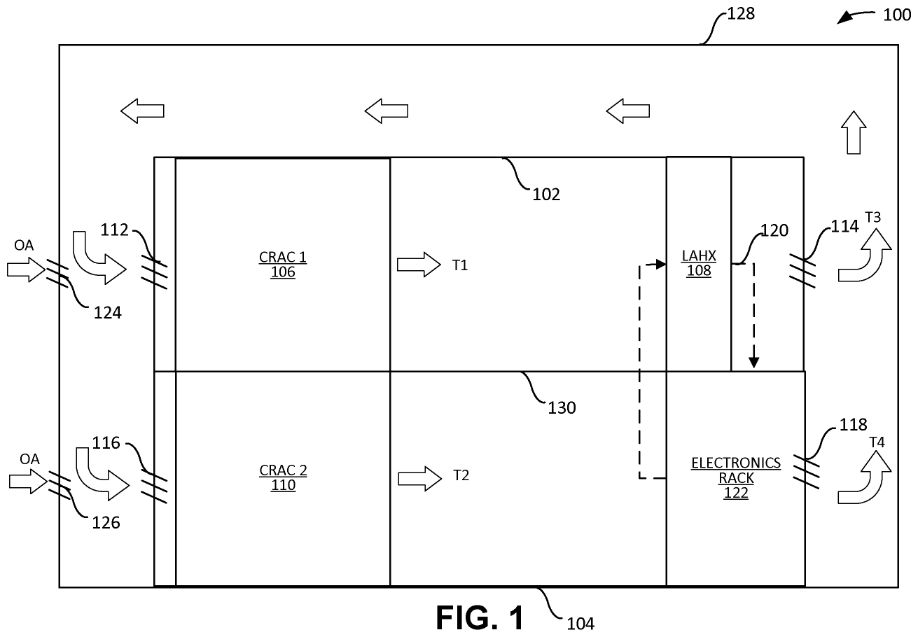

FIG. 1 schematically depicts an example parallel hybrid conditioning system in accordance with this disclosure. A parallel hybrid conditioning system (PHCS) 100 can be employed for a variety of practical applications and in combination with various other HVAC components and/or systems. Generally speaking, the conditioning system 100 functions to remove heat from a data server thereby improving performance of electrical components located therein using a combination of air cooling and liquid cooling techniques. In an example, CRAC units produce cool air to ambiently cool an electronics rack and cooling fluid in the LAHX in parallel. The LAHX further supplies liquid cooling to components of the electronics rack and transfers heat from the rack cool air supplied by the CRAC units. Example conditioning systems described herein can independently cool each of the electronics rack and cooling fluid in the LAHX. Thus, the CRAC units can supply different temperature of cooling to the electronics rack than the temperature of cooled air supplied to cooling fluid in the LAHX. Independent, parallel cooling of the electronics rack and cooling fluid in the LAHX can reduce energy consumption or water consumption by the system 100 and can increase the efficiency of cooling supplied to servers in a data center.

The parallel hybrid conditioning system 100 is structured, arranged, and configured to cool servers in a data center. In this example, the system 100 includes a first plenum 102, a second plenum 104, a first cooling component 106, a liquid to air heat exchanger (LAHX) 108, and a second cooling component 110. Herein, the first cooling component 106 and the second cooling component 110 can be referred to as the first computer room air conditioner (CRAC1) unit 106 and the second computer room air conditioner (CRAC2) unit 110, respectively. In an example, the first plenum 102 directs a first air stream from a first inlet 112 to a first outlet 114 and the second plenum 104 directs a second air stream from a second inlet 116 to a second outlet 118. Supply air, such as return air or outdoor air, is distributed in parallel to the first plenum 102 and the second plenum 104 to become the first air stream and the second air stream flowing through each respective plenum. Thus, the second air stream is directed through the second plenum 104 in parallel with the first air stream directed through the first plenum 102. In an example, as depicted in FIG. 1, the CRAC1 unit 106 cools the first air stream and the CRAC2 unit 110 cools the second air stream. Also, a single CRAC unit such as the CRAC2 unit 110 can at least partially cool both the first air stream and the second air stream. The first air stream cools cooling fluid in the LAHX 108, and the second air stream cools an electronics rack 122. The term electronics rack as used herein can describe several arrangements of one or more electronic components. While the electronics rack herein can be a single server rack, the rack can also represent multiple racks arranged in a row. For instance, the electronics rack 122 can represent more than one rack extending e.g., into or out of the page in a row. Likewise, the LAHX's described and depicted herein can represent multiple exchangers serving the multiple electronics racks in the row, or the LAHX's can each represent single heat exchangers serving one or more racks.

In an example, the LAHX 108 is arranged inside the first plenum 102 downstream from the CRAC1 unit 106, and the first air stream is used by the LAHX 108 to cool a first cooling liquid in a rack cooling liquid circuit 120 fluidly connected to the LAHX 108 and the electronics rack 122. The first cooling liquid which has been cooled by the LAHX 108 is supplied to the electronics rack 116 for liquid cooling of electrical components of the rack 122. In an example, the LAHX 108 is a rear door heat exchanger (RDHX). The RDHX device can be an active RDHX or a passive RDHX, and exchanges heat from the return air with circulating liquid, such as non-electrolyte solution, from a chiller or cooling tower. The LAHX can also be a type of cooling coil. Cooling coils are commonly formed of coiled copper tubes embedded in a matrix of fins. In another example, the LAHX can be a polymer fluid cooler (PFC). Other example LAHXs that can be used include micro-channel heat exchangers or air plate exchangers.

In an example, the first cooling liquid primarily cools one or more active components of the rack 122. The active components, e.g., control processing units (CPUs) or graphics processing units (GPUs), can be components of the server that require heat removal at rates which are beyond the capabilities of some conditioning systems supplying only air cooling. The first cooling liquid can also cool passive components of the rack, e.g., power supply units (PSUs), random access memory (RAM), hard drives, motherboards, or other circuitry. Example conditioning systems can also use the first cooling liquid to cool a combination of active and passive components. The first cooling liquid can be a two-phase coolant such as a dielectric coolant or refrigerant. Other cooling liquids can similarly be used, e.g., water, liquid desiccants, glycols, or fluorocarbon refrigerants.

In an example, the electronics rack 122 is arranged inside the second plenum 104 downstream from the CRAC2 unit 106, and the second air stream directly and sensibly cools the electronics rack. The electronics rack 122 can include or use one or more fans that draw the second air stream through, e.g., a chassis of the rack 122, and electrical components of the rack 122 can reject heat into the second air stream. In an example, the second air stream primarily functions to sensibly cool one or more passive components of the rack 122, e.g., PSUs, RAM, hard drives, motherboards, or other circuitry. The second air stream can also at least partially cool one or more active components of the rack 122, e.g., CPUs or GPUs.

The first air stream can exit the first plenum 102 at the first plenum outlet 114, and the second air stream can exit the second plenum 104 at the second plenum outlet 118. The first air stream and the second air stream accept heat from cooling fluid in the LAHX and the electronics rack, respectively, prior to such exiting. Thus, the temperature T3 of the first air stream exiting the first plenum 102 and the first plenum outlet 114 is higher than the temperature T1 of the first air stream exiting the CRAC1 unit. Likewise, the temperature T4 of the second air stream exiting the second plenum 104 and the second plenum outlet 118 is higher than the temperature T2 of the second air stream exiting the CRAC2 unit. In an example, the first air stream having exited at outlet 114 at temperature T3 is recirculated as return air and the second air stream having exited at outlet 118 at temperature T4 is recirculated as return air. In an example as depicted in FIG. 1, return air can be supplied to the first plenum inlet 112 or the second plenum inlet 116 by a return plenum or duct 128. In an example depicted in FIG. 1, return air from the first air stream and second air stream is combined in the return plenum 128 after exiting outlet 114 and outlet 118, respectively, and distributed to the first plenum inlet 112 and the second plenum inlet 116 in parallel.

In an example depicted in FIG. 1, the CRAC1 unit 106 cools the first air stream at a first temperature T1 and the CRAC2 unit 110 cools the second air stream at a second temperature T2. The CRAC1 unit 106 and CRAC2 unit 110 supply air at T1 and T2, respectively, based on e.g., the cooling requirements of the electronics rack. In an example, the temperature T1 of the first air stream is higher than the temperature T2 of the second air stream. This can be the case where the air temperature T1 required to by the LAHX to cool the rack cooling liquid circuit 120 is higher than the air temperature T2 required for direct sensible air cooling of, e.g., passive components of the rack 122. In another example, the temperature T1 of the first air stream can be less than temperature T2 of the second air stream. In an example, T1 or T2 can be modulated based on, e.g., a processing load of the server and cooling requirements of components therein. CRAC1 unit 106 and CRAC2 unit 110 can be operated to help supply the required temperature of the first air stream and second air stream, respectively. Example systems described herein can also include one or more dampers (e.g., 124 and 126 in FIG. 1) which can be selectively controlled to introduce outdoor air into the first plenum 102 or the second plenum 104. In an example depicted in FIG. 1, the one or more dampers can introduce outdoor air into the return plenum 128 which is later distributed to the first plenum inlet 112 and the second plenum inlet 116 in parallel. The one or more dampers can also allow outdoor air to enter the first plenum 102 or the second plenum 104 directly. The dampers can be located upstream or downstream the CRAC1 unit 106 or the CRAC2 unit 110. In an example, dampers 124 or 126 introduce outdoor air into the first plenum or the second plenum based on e.g., outdoor air conditions. For example, when the outdoor air is relatively cool, the outdoor air is introduced into the system by the dampers 124 or 126 to e.g., reduce the cooling load of the CRAC1 unit or the CRAC2 unit.

In an example, the first plenum 102 is located adjacent to the second plenum 104. The LAHX 108 is an RDHX which can be attached to a top surface of the chassis of the rack 122. The LAHX 108 is fluidly connected to the rack 122 to deliver the cooled first cooling liquid for direct liquid cooling of components within the rack 122. The CRAC1 unit can be mounted atop the CRAC2 unit, and a partition 130 divides the first plenum 102 and the second plenum 104. At least a portion of the first plenum 102 or second plenum 104 can be space beneath a raised floor, space above a suspended or lowered ceiling, or other contained space within the data center. Air that exits the first outlet 114 and the second outlet 118 and into the return plenum or duct 128. At least a portion of the return plenum 128 can be space beneath a raised floor, space above a suspended or lowered ceiling, or other contained space within the data center. Also, at least a portion of the return plenum 128 can be ducting, piping, or other type of conduit through which the return air can pass. In another example, the first plenum 102 is located remote from the second plenum 104. The first plenum can be located in e.g., a separate room within the data center. Here, the LAHX 108 is fluidly connected to the rack 122 despite being located remote from the rack. Where the LAHX 108 located remote from the rack 122, the LAHX 108 is fluidly connected via e.g., piping or conduit to supply liquid cooling to the rack 122.

While conditioning system 100 is depicted herein as having the first plenum 102, the second plenum 104, and the return plenum 128 each being contained spaces, the systems described herein can include or use the plenums being at least partially fluidly connected. Example systems can use similar air travel to that depicted e.g., in FIG. 1 in e.g., an open-air environment wherein air in the data center is not completely contained in the first plenum 102, the second plenum 104, or the return plenum 128. Here, the first air stream passing through the first plenum 102 and the second air stream passing through the second plenum 104 can be fluidly connected, and barriers, e.g., the partition 130, need not be included in the system 100. In such an open-air environment, the first air stream, the second air stream, or a return air stream can substantially circulate similar to that previously described without the need for completely contained plenums or ducts. Here, part of the second air stream and the first air stream can mix after being cooled by the CRAC1/CRAC2 and prior to cooling cooling fluid in the LAHX/RACK. However, the temperature T2 of the cooled air supplied by the CRAC2 unit 110 to the rack 122 can be less than the temperature T1 of the cooled air supplied by the CRAC1 unit 106 to the LAHX 108 despite the first air stream partially mixing with the second airstream. The open-air environment is not specifically described with respect to for the various conditioning systems described below. However, it is recognized that the other conditioning systems can include use a similar open-air environment with respect to the first plenum, second plenum, or the return plenum. Various conditioning systems described herein can circulate air streams in an open-air environment similar to that otherwise described with respect to contained plenums herein.

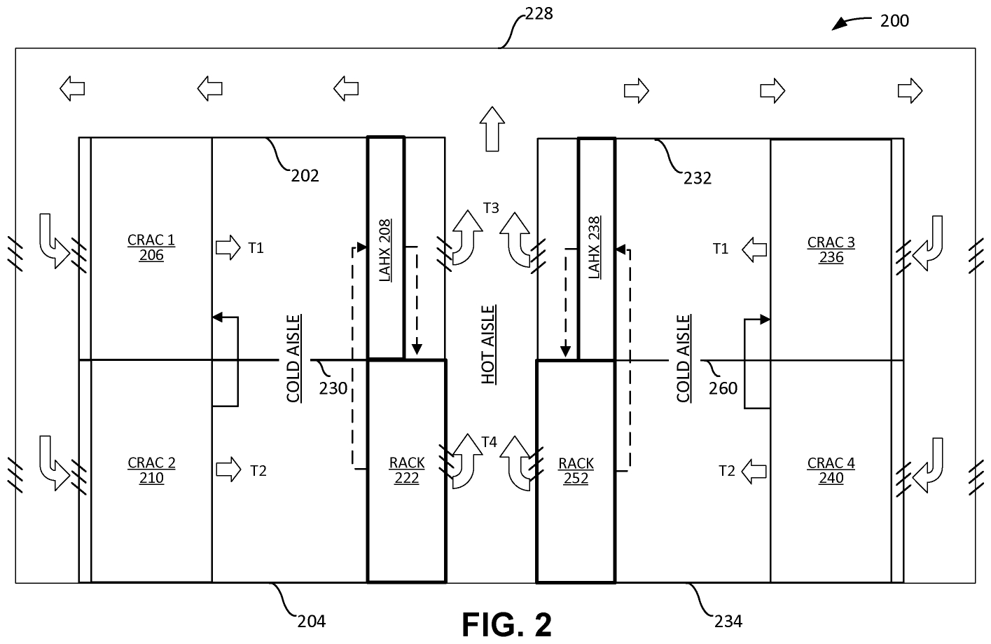

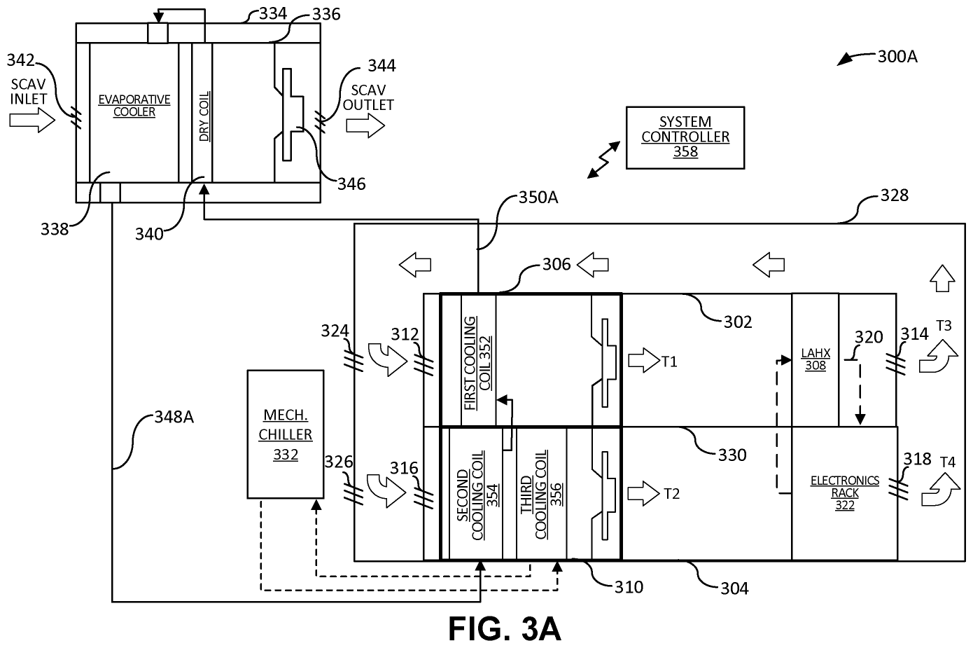

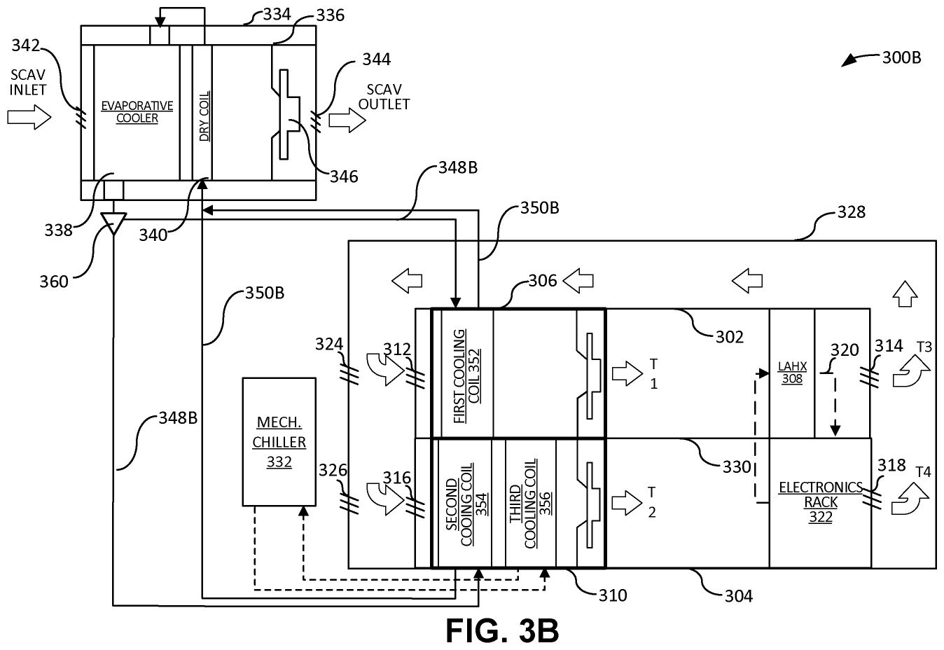

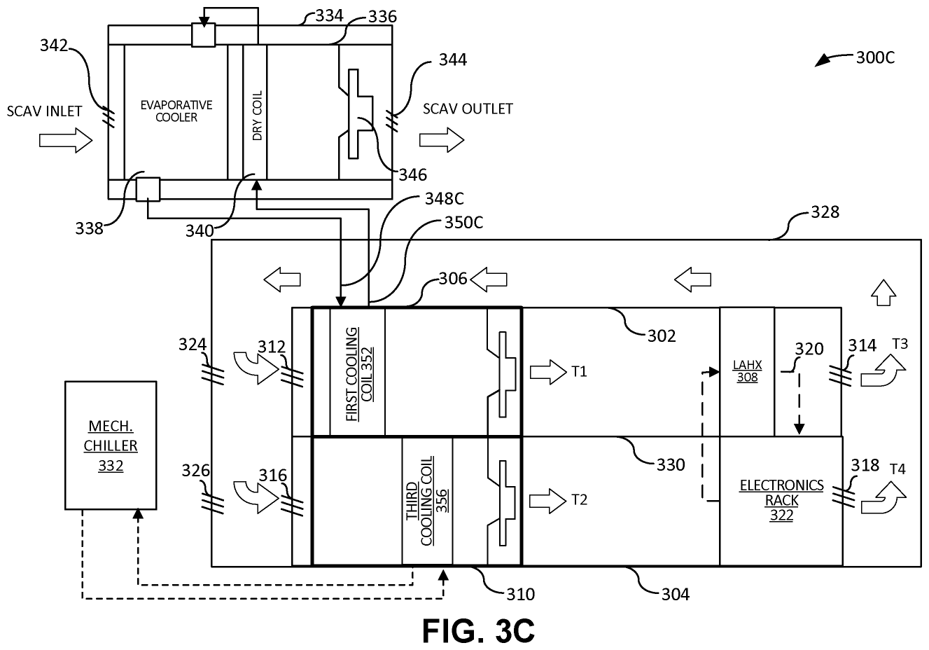

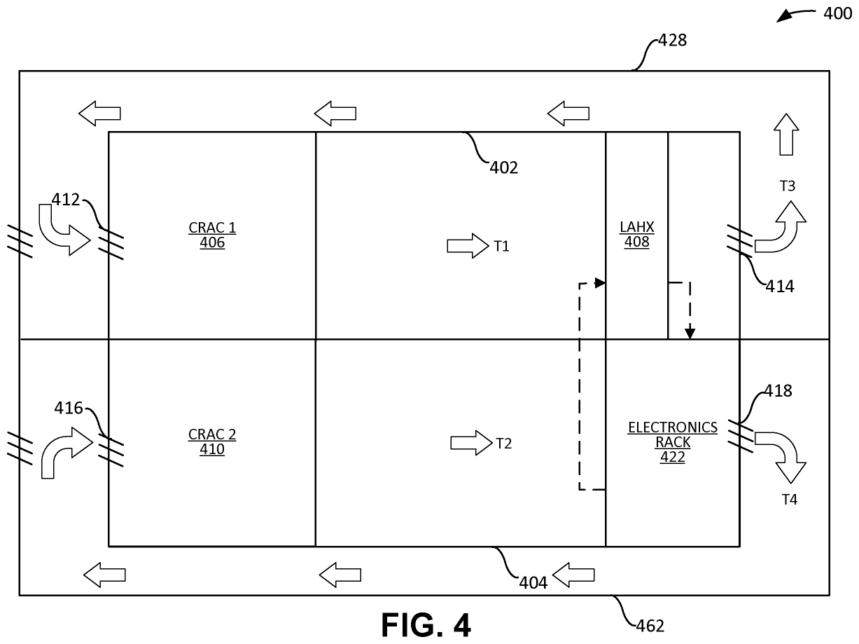

FIG. 2 schematically depicts another example parallel hybrid conditioning system (PHCS) in accordance with this disclosure. The conditioning system 200 is similar to that which was previously described with respect to conditioning system 100. Here, cooling components are similarly arranged to provide cooling to multiple racks. In an example, the conditioning system 200 can be similar to two opposing conditioning systems 100, as depicted in FIG. 1, each having opposite air flow paths with respect to each other. Although herein the conditioning system 200 is primarily described with reference to multiplicities of components of the conditioning system 100, components of similar conditioning systems described herein, e.g., cooling system 300 (as depicted in FIG. 3A-FIG. 3C) and cooling system 400 (as depicted in FIG. 4) can also be included in conditioning system 200. Conditioning system 200 includes a first plenum 202, a second plenum 204, a first cooling component 206, a first liquid to air heat exchanger (LAHX1) 208, and a second cooling component 210. Additionally, conditioning system 200 includes a third plenum 232, a fourth plenum 234, a third cooling component 236, a second liquid to air heat exchanger (LAHX2) 238, and a fourth cooling component 240. Herein, the first cooling component 206 and the second cooling component 210 can be referred to as the first computer room air conditioner (CRAC1) unit 210 and the second computer room air conditioner (CRAC2) unit 240, respectively. Also herein, the third cooling component 236 and the fourth cooling component 240 can be referred to as the third computer room air conditioner (CRAC3) unit 236 and the fourth computer room air conditioner (CRAC4) unit 240, respectively. In an example, as depicted in FIG. 2, the CRAC1 unit 206 cools the first air stream in the first plenum 202 and the CRAC2 unit 210 cools the second air stream in the second plenum 204. Likewise, the CRAC3 unit 236 cools a third air stream in the third plenum 232 and the CRAC4 unit 240 cools a fourth air stream in the fourth plenum 234. Also, a single CRAC unit, e.g., CRAC2 unit 210 or CRAC4 unit 240, can at least partially cool more than one air stream. The first air stream cools cooling fluid in the LAHX1 208, and the second air stream cools a first electronics rack 222. Likewise, the third air stream cools cooling fluid in the LAHX2 238, and the fourth air stream cools a second electronics rack 252. While the electronics racks herein can each be a single server rack, the racks can also represent multiple racks arranged in a row. For instance, the electronics rack 222 can represent more than one rack extending e.g., into or out of the page in a row. Likewise, the LAHX's described and depicted herein can represent multiple exchangers serving the multiple electronics racks in the row, or the LAHX's can each represent single heat exchangers serving one or more racks.

FIG. 2 shows CRAC1/CRAC2 providing cooling to the first rack 222 and CRAC3/CRAC4 providing cooling to the second rack 252. The first rack 222 and the second rack 252 can be arranged back-to-back, and hot air exiting the first/second plenums and third/fourth plenums can combine in a hot aisle between the first rack 222 and the second rack 252. The space in the first/second plenums between CRAC1/CRAC2 and LAHX1/first rack 222 can define a cold aisle since the space therebetween supplies cooled air. Likewise, the space in the third/fourth plenums between CRAC3/CRAC4 and LAHX2/second rack 252 can define a cold aisle since the space therebetween is used to supply cooled air. In an example, system 200 includes fluidly contained cold aisles, wherein cold air from e.g., the first air stream and the second air stream are contained in the first plenum and the second plenum, respectively. Further, the fluidly contained cold aisles can each include two fluidly isolated cold chambers separated by e.g., a first partition 230 or a second partition 260. Since each example cold aisle contains two isolated cold chambers, each cold aisle can deliver cold air at two different temperatures. For instance, the cold aisle supplying the first rack 222 can supply cold air at two different temperatures, T1 and T2. Likewise, the cold aisle supplying the second rack 252 can supply cold air at two different temperatures, T3 and T4. In an example, the temperature T1 of the first air stream can be greater than the temperature T2 of the second air stream, and the temperature T3 of the third air stream can be greater than the temperature T4 of the fourth air stream. Example systems can include or use open-air hot aisles, wherein a return plenum 228 is the ambient space in a room of a data center. Also, example systems can include or use contained hot aisles wherein the return plenum 228 is enclosed ducting or conduit which circulates return air to several CRAC unit inlets.

As previously described, the first rack 222 and the second rack 252 can each represent a row of several racks, i.e., a first row 222 and a second row 252. Each rack in the first row 222 and the second row 252 can have its own LAHX, or one or more LAHX's can provide liquid cooling to several racks in the first row 222 or the second row 252. In an example, the CRAC1 unit 206 can supply cooled air in the first air stream to cool multiple LAHX's in a row (as represented by LAHX 208 in FIG. 2). Likewise, the CRAC2 unit 210 can supply cooled air in the second air stream to cool several racks in the first row 222. CRAC3/CRAC4 can function similarly with regard to their respective components.

FIG. 3A, FIG. 3B, & FIG. 3C schematically depict example parallel hybrid conditioning systems (PHCS) in accordance with this disclosure. The conditioning system 300 can be substantially similar to conditioning system 100 of the example of FIG. 1. The components, structures, configuration, functions, etc. of system 300 can therefore be the same as or substantially similar to that described in detail above with reference to system 100. In an example, the conditioning system 300 includes or uses a first liquid cooler (LC1) 334 fluidly connected to at least one of a CRAC1 unit 306 or a CRAC2 unit 310. The CRAC1 unit 306 functions to provide air cooling to cooling fluid in the LAHX 308, and the LAHX 308 provides liquid cooling using a first cooling liquid to components of the electronics rack 322 through a rack cooling liquid circuit 320. The CRAC2 unit 310 functions to provide air cooling directly to the electronics rack 322. LC1 can be an external liquid cooler located remote from an electronics rack 322, a first plenum 302, a second plenum 304, and a return plenum 328. In an example, the LC1 334 functions to supply one or more CRAC units with a pre-cooled cooling liquid, also referred to herein as a second cooling liquid, for cooling one or more air streams located in one or more plenums. In some examples, the LC1 can be a primary source a precooled cooling liquid supply for one or more of the CRAC units.

The CRAC units can each define a CRAC plenum including or using one or more cooling coils therein. For example, the CRAC1 unit 306 can include or use a first cooling coil 352, and the CRAC2 unit 310 can include or use a second cooling coil 354 and a third cooling coil 356. In another example, the CRAC units can each include two or more cooling coils. Each of the CRAC units can include or use a fan to cause a return air stream to flow from inlets 312 and 316 through the CRAC1 unit 306 and the CRAC2 unit 310, respectively. Outdoor air can also be introduced e.g., into the return plenum at inlets 324 and 326 to flow through the CRAC units.

In an example depicted in FIG. 3A, LC1 334 includes scavenger air plenum 336 having scavenger inlet 342 and scavenger outlet 344, evaporative cooler (EC) 338, dry coil 340, and fan 346. Similar to that previously described with respect to conditioning system 100, the CRAC1 unit 306 functions to cool a first air stream flowing in a first plenum 302 from a first inlet 312 to a first outlet 314, and the CRAC2 unit 310 functions to cool a second air stream flowing in a second plenum 304 from a second inlet 316 to a second outlet 318. A partition 330 can separate the first plenum 302 from the second plenum 304. Air exiting the first plenum 302 and second plenum 304 can be returned to the CRAC units in the return plenum 328 for recycled use. In the depiction of FIG. 3A, the LC1 334 supplies the pre-cooled second cooling liquid to both the CRAC1 306 and the CRAC2 310 in series. In an example, the LC1 334 supplies pre-cooled liquid to the second cooling coil 354 of the CRAC2 unit 310 and subsequently to the first cooling coil 352 of the CRAC1 unit 306. Here, the second cooling coil 354 and the first cooling coil 352 each use the pre-cooled second cooling liquid to lower the temperature of return air flowing through CRAC2 310 and CRAC1, respectively. In an example, the pre-cooled second cooling liquid is supplied from the LC1 334 through LC1 supply circuit 348 first to the CRAC2 unit 310 (which provides direct air cooling to the electronics rack 322) and subsequently to the CRAC1 unit (which provides air cooling to cooling fluid in the LAHX 308). In this example, the pre-cooled second cooling liquid can be supplied to the CRAC2 unit 310 at a lower temperature than the pre-cooled second cooling liquid is supplied to the CRAC1 unit 306. As such, the LC1 334 can supply a greater amount of cooling for direct air cooling of the electronics rack 322 and the LC1 334 can supply a lesser amount of cooling for air cooling of cooling fluid in the LAHX 308. Here, the temperature T2 of the second air stream flowing through the second plenum is lower than the temperature T1 of the first air stream flowing through the first plenum. In another example, the LC1 unit 334 supplies pre-cooled second cooling liquid in series, first to the CRAC1 unit 306 and subsequently to the CRAC2 unit 310. Here, the LC1 unit 334 can supply pre-cooled second cooling liquid to the CRAC1 unit 306 at a lower temperature than the pre-cooled second cooling liquid is supplied to the CRAC 2 unit 310. The second cooling liquid exiting the CRAC units can be recirculated to the LC1 334 through return circuit 350A. In an example, the second cooling liquid is recirculated to the LC1 334 at an inlet of the dry coil 340.

Dry coil 340 may also be referred to as a recovery coil and is a type of liquid-to-air heat exchanger. In other examples according to this disclosure, another type of LAHX may be employed in lieu of a dry coil. Scavenger air plenum 336 of LC1 334 includes scavenger inlet 342 and scavenger outlet 344 through which fan 346 can cause a scavenger air stream flow through one or both of EC 338 and dry coil 340, depending upon e.g., an operational mode of LC1 334. Scavenger plenum 336 can also be referred to as a housing, cabinet, or structure, and can be configured to house one or more components used to condition air or water. Scavenger plenum 336 and the conditioning components it houses can be disposed in various locations relative to the electronics rack 322, for example, outside of an enclosed space having electronics rack 322 or located external to a first plenum 302, a second plenum 304, or a return plenum 328 of the conditioning system. Additionally, scavenger air channeled through plenum 336 can be from various sources, including, in examples, outside air. More generally, scavenger air is air that is not what may be referred to as process air, which process air is used to directly condition temperature and/or humidity of a heat load, e.g., the electronics rack 322. In examples, a filter can be arranged inside scavenger plenum 336 near scavenger inlet 342. In other examples, the filter can be arranged inside scavenger plenum 336 near scavenger outlet 344. And, in other examples, one filter can be arranged inside scavenger plenum 336 near scavenger inlet 342, and another filter can be arranged inside scavenger plenum 336 near scavenger outlet 344.

The scavenger air entering plenum 336 can pass through EC 338. EC 338 can be configured to condition the second cooling liquid and/or the scavenger air passing there through using the second cooling liquid (may also be referred to in reference to operation of evaporative coolers as an evaporative liquid). EC 338 can use the cooling potential in both the air and the evaporative liquid to reject heat. In an example, as scavenger air flows through EC 338, the evaporative liquid, or both the scavenger air and the evaporative liquid, can be cooled to a temperature approaching the wet bulb (WB) temperature of the air entering plenum 336. Due to the evaporative cooling process in EC 338, a temperature of the second cooling liquid at outlet 344 of EC 338 can be less than a temperature of the second cooling liquid at inlet 342; and a temperature of the scavenger air exiting EC 338 in scavenger plenum 336 can be less than a temperature of the scavenger air entering EC 338. In some cases, a temperature reduction of the second cooling liquid can be significant, whereas in other cases, the temperature reduction can be minimal. Similarly, a temperature reduction of the scavenger air can range between minimal and significant. In some cases, the scavenger air temperature can increase across EC 338. Such temperature reduction of one or both of the second cooling liquid and the scavenger air can depend in part on the outdoor air conditions (temperature, humidity), and operation of EC 338 and/or dry coil 340.

EC 338 can be any type of evaporative cooler configured to exchange energy between an air stream and the second cooling liquid through evaporation of a portion of the liquid into the air. Evaporative coolers can include direct-contact evaporation devices in which the working air stream and the liquid water (or other liquid) stream that is evaporated into the air to drive heat transfer are in direct contact with one another. In what is sometimes referred to as “open” direct-contact evaporation devices, the liquid water may be sprayed or misted directly into the air stream, or alternatively the water is sprayed onto a filler material or wetted media across which the air stream flows. As the unsaturated air is directly exposed to the liquid water, the water evaporates into the air, and, in some cases, the water is cooled.

Such direct-contact evaporation devices can also include what is sometimes referred to as a closed-circuit device. Unlike the open direct-contact evaporative device, the closed system has two separate liquid circuits. One is an external circuit in which water is recirculated on the outside of the second circuit, which is tube bundles (closed coils) connected to the process for the hot liquid being cooled and returned in a closed circuit. Air is drawn through the recirculating water cascading over the outside of the hot tubes, providing evaporative cooling similar to an open circuit. In operation the heat flows from the internal liquid circuit, through the tube walls of the coils, to the external circuit and then by heating of the air and evaporation of some of the water, to the atmosphere.

These different types of evaporative coolers can also be packaged and implemented in specific types of systems. For example, a cooling tower can include an evaporative cooling device such as those described above. A cooling tower is a device that processes working air and water streams in generally a vertical direction and that is designed to reject waste heat to the atmosphere through the cooling of a water stream to a lower temperature. Cooling towers can transport the air stream through the device either through a natural draft or using fans to induce the draft or exhaust of air into the atmosphere. Cooling towers include or incorporate a direct-contact evaporation device/components, as described above.

Examples of evaporative coolers usable in the conditioning systems of the present application can also include other types of evaporative cooling devices, including liquid-to-air membrane energy exchangers. Unlike direct-contact evaporation devices, a liquid-to-air membrane energy exchanger (LAMEE) separates the air stream and the liquid water stream by a permeable membrane, which allows water to evaporate on the liquid water stream side of the membrane and water vapor molecules to permeate through the membrane into the air stream. The water vapor molecules permeated through the membrane saturate the air stream and the associated energy caused by the evaporation is transferred between the liquid water stream and the air stream by the membrane.

In at least some examples in which EC 338 is a LAMEE, the LAMEE can include a stack of alternating air and liquid channels, through which scavenger air and the second cooling liquid flow and in which each air channel is separated from a pair of adjacent liquid channels by permeable membranes. The liquid channels may be formed as polymer liquid panels, each of which direct the second cooling liquid through a plurality of liquid flow channels enclosed by permeable membranes affixed to opposing faces of the liquid panel. In examples, such a liquid panel can in include a plurality of liquid inlets and liquid outlets that are connected by a plurality of liquid flow channels. Additionally, in examples, each liquid inlet and each liquid outlet can direct the second cooling liquid into and out of a plurality of liquid flow channels.

Example LAMEE ECs in accordance with this disclosure can employ permeable membranes to separate the second cooling liquid and air flows/streams there through. The permeable membranes of the adjacent liquid panels of the LAMEE can be structured and configured to be permeable to water vapor, but not to other constituents that may be present in the second cooling liquid. Thus, generally anything in the second cooling liquid in a gas phase can pass through the membranes and generally anything in a liquid or solid phase cannot pass through the membranes. Such membranes can include porous, micro-porous, non-porous, and selectively permeable membranes, as examples. In examples, the membranes of example absorber-evaporator devices in accordance with this disclosure can be a micro-porous structure membrane formed as a thin film of a low surface energy polymer such as PTFE, polypropylene or polyethylene. The hydrophobic membrane resists penetration by the liquid due to surface tension, while freely allowing the transfer of gases, including water vapor, through the membrane pores. In examples, the membranes can be between about 20 to about 100 microns thick with a mean pore size of 0.1-0.2 micron.

Membrane exchangers may have some advantages over other types of evaporative coolers. For example, the LAMEE may eliminate or mitigate maintenance requirements and concerns of conventional cooling towers or other systems including direct-contact evaporation devices, where the water is in direct contact with the air stream that is saturated by the evaporated water. For example, the membrane barriers of the LAMEE inhibit or prohibit the transfer of contaminants and micro-organisms between the air and the liquid stream, as well as inhibiting or prohibiting the transfer of solids between the water and air.

In an example, the cooling (evaporative) liquid in EC 338 can be water or predominantly water. It is recognized that other types of evaporative second cooling liquids can be used in combination with water or as an alternative to water in the other conditioning systems described herein, including, for example, liquid desiccants.

Dry coil (or recovery coil) 340 is arranged inside plenum 336 downstream of EC 338. Dry coil 340 can be configured to sensibly cool the second cooling liquid flowing through the coil using the scavenger air. In some examples, dry coil 340 sensibly cools the second cooling liquid flowing through the coil using the scavenger air exiting EC 338. The scavenger air exiting EC 338 can, in some cases be relatively cool and additional sensible heat from the second cooling liquid passing through coil 340 can be rejected into the scavenger air. In some other examples in which EC 338 is bypassed or deactivated, dry coil 340 sensibly cools the second cooling liquid flowing through the coil using the scavenger air entering plenum 336 at (or at conditions at) scavenger inlet 342. In the examples of FIG. 3A FIG. 3B, and FIG. 3C (and some other examples according to this disclosure), dry coil 340 sensibly pre-cools the second cooling liquid returned to LC1 334 either of the CRAC1 unit 306 or the CRAC2 unit 310 using the scavenger air exiting EC 338. The pre-cooled second cooling liquid is transported from an outlet of the coil 340 to an inlet of the EC 338 to be recycled through the evaporative cooler. The pre-cooled second cooling liquid is then further pre-cooled by the evaporative cooler for eventual distribution to one of the CRAC units.

In some ambient conditions, LC1 334 may not be capable or desirable for precooling the liquid sufficiently to carry the load of, e.g., the CRAC2 310 for cooling the electronics rack 322 by direct air cooling. In some examples LC2 332 is included in or used by the conditioning system 300A for alternative or additional cooling of one or more of the CRAC units. In an example, the LC2 332 provides supplemental liquid cooling to the third cooling coil 356 of the CRAC2 unit 310, and the third cooling coil 356 further lowers the temperature of a second air stream flowing from the second inlet 316 to the second outlet 318. Here, the LC2 332 can supply supplemental liquid cooling to the CRAC2 unit 310 without supplying supplemental liquid cooling to the CRAC1 unit 306. In other examples, The LC2 332 can supply supplemental liquid cooling to a supplemental cooling coil of the CRAC1 unit 306. In one example, the LC1 can be fluidly coupled to LC2 332, which can provide trim cooling to the second cooling liquid in the delivered to second cooling coil 354 of the CRAC2 unit. In another example, as depicted in FIG. 3A, the LC2 332 can provide liquid cooling to the CRAC2 unit using a third cooling liquid supplied to the third cooling coil 356. Here the third cooling liquid can be fluidly isolated from the second cooling liquid. In some examples, the LC2 332 is a mechanical chiller, e.g., a vapor compression cycle mechanical chiller using synthetic refrigerants. LC2 332 can also be a variety of devices configured to cool the cooling liquid, including, generally, liquid-to-air or liquid-to-liquid heat exchangers (LAHX and LLHX, respectively), chillers, dry coolers, cooling towers, adiabatic coolers, absorption coolers, or any other type of evaporative cooler or hybrid cooler, or a combination thereof.

System controller 358 can include hardware, software, and combinations thereof to implement the functions attributed to the controller herein. System controller 358 can be an analog, digital, or combination analog and digital controller including a number of components. As examples, controller 358 can include ICB(s), PCB(s), processor(s), data storage devices, switches, relays, etcetera. Examples of processors can include any one or more of a microprocessor, a controller, a digital signal processor (DSP), an application specific integrated circuit (ASIC), a field-programmable gate array (FPGA), or equivalent discrete or integrated logic circuitry. Storage devices, in some examples, are described as a computer-readable storage medium. In some examples, storage devices include a temporary memory, meaning that a primary purpose of one or more storage devices is not long-term storage. Storage devices are, in some examples, described as a volatile memory, meaning that storage devices do not maintain stored contents when the computer is turned off. Examples of volatile memories include random access memories (RAM), dynamic random-access memories (DRAM), static random-access memories (SRAM), and other forms of volatile memories known in the art. The data storage devices can be used to store program instructions for execution by processor(s) of controller 358. The storage devices, for example, are used by software, applications, algorithms, as examples, running on and/or executed by controller 358. The storage devices can include short-term and/or long-term memory and can be volatile and/or non-volatile. Examples of non-volatile storage elements include magnetic hard discs, optical discs, floppy discs, flash memories, or forms of electrically programmable memories (EPROM) or electrically erasable and programmable (EEPROM) memories.

System controller 358 can be configured to communicate with conditioning system 300A and components thereof via various wired or wireless communications technologies and components using various public and/or proprietary standards and/or protocols. For example, a power and/or communications network of some kind may be employed to facilitate communication and control between controller 358 and conditioning system 300A. In one example, system controller 358 can communicate with conditioning system 300A via a private or public local area network (LAN), which can include wired and/or wireless elements functioning in accordance with one or more standards and/or via one or more transport mediums. In one example, controller 358 and system 300A can be configured to use wireless communications according to one of the 802.11 or Bluetooth specification sets, or another standard or proprietary wireless communication protocol. Data transmitted to and from components of system 300A, including controller 358, can be formatted in accordance with a variety of different communications protocols. For example, all or a portion of the communications can be via a packet-based, Internet Protocol (IP) network that communicates data in Transmission Control Protocol/Internet Protocol (TCP/IP) packets, over, for example, Category 5, Ethernet cables.

System controller 358 can selectively operate several components in example conditioning systems included herein. System controller 358 can include one or more programs, circuits, algorithms or other mechanisms for controlling the operation of conditioning system 300A. For example, system controller 358 can be configured to modulate the speeds of the fans, or operation of dampers in conditioning systems described herein. Additionally, controller 358 can be configured to control operation of valves, pumps, or other devices located within the rack liquid circuit 320, the supply circuit 348A, the return circuit 350A, or a supplemental circuit configured to supply the third cooling liquid from the LC2 332.

A system controller is not specifically shown in all of the figures for the various conditioning systems described herein. However, it is recognized that the other conditioning systems can include a system controller, which is similarly structured and configured, and which operates similar to system controller 358.

FIG. 3B and FIG. 3C depict alternative examples of conditioning system 300A. In FIG. 3B, the conditioning system 300B includes the LC1 334 which supplies the pre-cooled second cooling liquid to both the CRAC1 306 and the CRAC2 310 in parallel. Here, a supply circuit 348B can supply the second cooling fluid to the first cooling coil 352 and the second cooling coil 354 in parallel. In an example, the LC1 334 can supply a relatively equal amount or flow rate of the second cooling fluid to each of the CRAC1 306 and the CRAC2 310. In another example, the conditioning system 300B can include or use a distribution valve 360 which can be controlled such as to modulate the distribution of the second cooling fluid between the CRAC1 306 and the CRAC2 310 in parallel. The second cooling fluid can be recycled to the LC1 334 in a return circuit 350B. In an example, the cooling fluid can be return from the CRAC1 306 and the CRAC2 310 to the LC1 334 in the return circuit 350B in parallel. In other examples, the cooling liquid can return to the LC1 from the CRAC units in series. In FIG. 3C, the conditioning system 300C does not include the second cooling coil 354. Here, the LC1 334 supplies the second cooling fluid exclusively to the CRAC1 306 without supplying liquid cooling to the CRAC2. Here, the CRAC2 can rely on the LC2 332 as a primary or sole source of liquid cooling supplied to, e.g., the third cooling coil 356. Distribution of the second cooling liquid from the LC1 334 to the CRAC units, as described above with respect to each of the conditioning systems 300A, 300B, and 300C, can utilize parallel or series liquid circuits connected to one or both of the CRAC1 unit 306 and the CRAC2 unit 310. The liquid circuits described above can be combined or can be formed by larger liquid circuits including or using valves determining similar liquid distribution.

FIG. 4 schematically depicts another example parallel hybrid conditioning system (PHCS) in accordance with this disclosure. The conditioning system 400 can be substantially similar to conditioning system 100 of the example of FIG. 1 and conditioning systems 300A, 300B, and 300C of the examples of FIGS. 3A, 3B, and 3C, respectively. The components, structures, configuration, functions, etc. of system 400 can therefore be the same as or substantially similar to that described in detail above with reference to systems 100, 300A, 300B, or 300C. Conditioning system 400 includes CRAC1 406 located in a first plenum 402 upstream an LAHX 408. A first air stream can flow through the first plenum from a first inlet 412 to a second outlet 418. The conditioning system 400 also includes CRAC2 410 located in a second plenum 404 upstream an electronics rack 422. A second air stream can flow through the second plenum from a second inlet 416 to a second outlet 418. In the example depicted in FIG. 4, air is recirculated through each of the first plenum 402 and the second plenum 404 separately. The first air stream exits the first plenum 402 at the first outlet 414 and enters a first return plenum 428 where it is returned to the first inlet 412. The second air stream exits the second plenum 404 at the second outlet 418 and enters the second return plenum 462 where it is returned to the second inlet 416. Example system 400 can include one or more dampers between the first return plenum 428 and the second return plenum 462 such as to enable control of return air mixture between a first return air stream in the first return plenum 428 and a second return air stream in the second return plenum 462.

### EXAMPLES AND NOTES

Example 1 is a conditioning system comprising: a first plenum configured to direct a first air stream from a first inlet to a first outlet; a second plenum configured to direct a second air stream from a second inlet to a second outlet in parallel with the first air stream directed through the first plenum; a first cooling component arranged inside the first plenum and configured to cool the first air stream; a liquid to air heat exchanger (LAHX) arranged inside the first plenum and downstream the first cooling component, the LAHX being fluidly connected to a rack cooling liquid circuit and configured to cool a first cooling liquid in the rack cooling liquid circuit using the first air stream; and a second cooling component arranged inside the second plenum and configured to cool the second air stream, wherein: the rack cooling liquid circuit is configured to be fluidly connected and configured to provide liquid cooling to one or more electronic components arranged inside the second plenum downstream of the second cooling component; and the second air stream cooled by the second cooling component is configured to sensibly cool the one or more electronic components.

In Example 2, the subject matter of Example 1, further comprising a return duct configured to recirculate air exiting the first outlet and the second outlet back to the first inlet and the second inlet.

In Example 3, the subject matter of any of Examples 1-2, further comprising a return plenum connected to the first outlet and the second outlet, the first air stream and the second air stream flowing through the first outlet and the second outlet, respectively, into and mixing in the return plenum.

In Example 4, the subject matter of Example 3, further comprising a return duct connected to the return plenum configured to recirculate air from the return plenum back to the first inlet and the second inlet.

In Example 5, the subject matter of any of Examples 1-4, further comprising: a first set of bypass dampers configured to direct outdoor air into the first plenum; and a second set of bypass dampers configured to direct outdoor air into the second plenum.

In Example 6, the subject matter of any of Examples 1-5, further comprising: a second cooling liquid circuit; and an external liquid cooler configured to cool a second cooling liquid circulating through the second cooling liquid circuit; wherein the first cooling component is fluidly connected to the second cooling liquid circuit and configured to use the second cooling liquid in the second cooling liquid circuit to cool the first air stream.

In Example 7, the subject matter of Example 6, wherein the external liquid cooler comprises an evaporative cooler configured to use outdoor air to evaporatively cool the second cooling liquid in the second cooling liquid circuit.

In Example 8, the subject matter of Example 7, wherein the evaporative cooler is a liquid to air membrane energy exchanger (LAMEE).

In Example 9, the subject matter of any of Examples 6-8, wherein the second cooling component is fluidly connected to the second cooling liquid circuit and configured to use the second cooling liquid in the second cooling liquid circuit to cool the second air stream.

In Example 10, the subject matter of any of Examples 6-9, further comprising: a first set of bypass dampers configured to direct outdoor air into the first plenum; and a second set of bypass dampers configured to direct outdoor air into the second plenum; wherein: the first set of bypass dampers are opened to introduce outdoor air into the first air stream; and operation of the external liquid cooler is modulated based on a temperature of the outdoor air.

In Example 11, the subject matter of Example 10, further comprising a system controller, wherein the system controller is configured to: selectively open at least one of the first set of bypass dampers and the second set of bypass dampers; and modulate operation of the external liquid cooler based at least on a temperature of the outdoor air.

In Example 12, the subject matter of any of Examples 6-11, wherein the second cooling component comprises at least one liquid to air heat exchanger (LAHX) fluidly connected to the second cooling liquid circuit and configured to cool the second air stream using the second cooling liquid.

In Example 13, the subject matter of Example 12, wherein the second cooling component further comprises a mechanical cooling component configured to selectively cool the second air stream.

In Example 14, the subject matter of any of Examples 1-13, wherein second cooling component cools the second air stream to a lower temperature than the first cooling component cools the first air stream.

Example 15 is a method of providing cooling to a heat load, the method comprising: directing a first air stream through a first plenum from a first inlet to a first outlet; directing a second air stream through a second plenum from a second inlet to a second outlet, the second air stream being directed in parallel with the first air stream directed through the first plenum; cooling the first air stream using a first cooling component arranged inside the first plenum; cooling a first cooling liquid circulating through a liquid to air heat exchanger (LAHX) using the first air stream circulating through the LAHX, the LAHX arranged inside the first plenum and downstream the first cooling component; cooling the second air stream using a second cooling component arranged inside the second plenum; cooling one or more electronic components arranged inside the second plenum downstream of the second cooling component using the first cooling liquid; and cooling the one or more electronic components using the second air stream cooled by the second cooling component.

In Example 16, the subject matter of Example 15, further comprising recirculating the first air stream or the second air stream through a return duct by directing air exiting the first outlet or the second outlet, respectively, back to the first inlet or the second inlet, respectively.

In Example 17, the subject matter of any of Examples 15-16, further comprising mixing the first air stream and the second air stream within a return plenum connected to the first outlet and the second outlet, the first air stream and the second air stream flowing through the first outlet and the second outlet, respectively.

In Example 18, the subject matter of Example 17, further comprising recirculating air from the return plenum back to the first inlet and the second inlet using a return duct connected to the return plenum.

In Example 19, the subject matter of any of Examples 15-18, further comprising: selectively directing outdoor air into the first plenum using a first set of bypass dampers; and selectively directing outdoor air into the second plenum using a second set of bypass dampers.

In Example 20, the subject matter of any of Examples 15-19, further comprising: cooling a second cooling liquid circulating through a second cooling liquid circuit using an external liquid cooler; and using the second cooling liquid in the second cooling liquid circuit to cool the first air stream.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20. Example 24 is a method to implement of any of Examples 1-20.

The above description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein. In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Geometric terms, such as “parallel”, “perpendicular”, “round”, or “square”, are not intended to require absolute mathematical precision, unless the context indicates otherwise. Instead, such geometric terms allow for variations due to manufacturing or equivalent functions. For example, if an element is described as “round” or “generally round,” a component that is not precisely circular (e.g., one that is slightly oblong or is a many-sided polygon) is still encompassed by this description.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer readable instructions for performing various methods. The code can form portions of computer program products. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) can be used in combination with each other. Other embodiments can be used, such as by one of ordinary skill in the art upon reviewing the above description. The Abstract is provided to comply with 37 C.F.R. § 1.72 (b), to allow the reader to quickly ascertain the nature of the technical disclosure. It is submitted with the understanding that it will not be used to interpret or limit the scope or meaning of the claims. Also, in the above Detailed Description, various features can be grouped together to streamline the disclosure. This should not be interpreted as intending that an unclaimed disclosed feature is essential to any claim. Rather, inventive subject matter can lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A conditioning system comprising:
a first plenum configured to direct a first air stream from a first inlet to a first outlet;
a second plenum configured to direct a second air stream from a second inlet to a second outlet in parallel with the first air stream directed through the first plenum;
a first cooling component arranged inside the first plenum and configured to cool the first air stream;
a liquid to air heat exchanger (LAHX) arranged inside the first plenum and downstream the first cooling component, the LAHX being fluidly connected to a rack cooling liquid circuit and configured to cool a first cooling liquid in the rack cooling liquid circuit using the first air stream; and
a second cooling component arranged inside the second plenum and configured to cool the second air stream, wherein:
the rack cooling liquid circuit is configured to be fluidly connected and configured to provide liquid cooling to one or more electronic components arranged inside the second plenum downstream of the second cooling component; and
the second air stream cooled by the second cooling component is configured to sensibly cool the one or more electronic components.

2. The conditioning system of claim 1, further comprising a return duct configured to recirculate air exiting the first outlet and the second outlet back to the first inlet and the second inlet.

3. The conditioning system of claim 1, further comprising a return plenum connected to the first outlet and the second outlet, the first air stream and the second air stream flowing through the first outlet and the second outlet, respectively, into and mixing in the return plenum.

4. The conditioning system of claim 3, further comprising a return duct connected to the return plenum configured to recirculate air from the return plenum back to the first inlet and the second inlet.

5. The conditioning system of claim 1, further comprising:
a first set of bypass dampers configured to direct outdoor air into the first plenum; and
a second set of bypass dampers configured to direct outdoor air into the second plenum.

6. The conditioning system of claim 1, further comprising:
a second cooling liquid circuit; and
an external liquid cooler configured to cool a second cooling liquid circulating through the second cooling liquid circuit;
wherein the first cooling component is fluidly connected to the second cooling liquid circuit and configured to use the second cooling liquid in the second cooling liquid circuit to cool the first air stream.

7. The conditioning system of claim 6, wherein the external liquid cooler comprises an evaporative cooler configured to use outdoor air to evaporatively cool the second cooling liquid in the second cooling liquid circuit.

8. The conditioning system of claim 7, wherein the evaporative cooler is a liquid to air membrane energy exchanger (LAMEE).

9. The conditioning system of claim 6, wherein the second cooling component is fluidly connected to the second cooling liquid circuit and configured to use the second cooling liquid in the second cooling liquid circuit to cool the second air stream.

10. The conditioning system of claim 6, further comprising:
a first set of bypass dampers configured to direct outdoor air into the first plenum; and
a second set of bypass dampers configured to direct outdoor air into the second plenum;
wherein:
the first set of bypass dampers are opened to introduce outdoor air into the first air stream; and
operation of the external liquid cooler is modulated based on a temperature of the outdoor air.

11. The conditioning system of claim 10, further comprising a system controller, wherein the system controller is configured to:
selectively open at least one of the first set of bypass dampers and the second set of bypass dampers; and
modulate operation of the external liquid cooler based at least on a temperature of the outdoor air.

12. The conditioning system of claim 6, wherein the second cooling component comprises at least one liquid to air heat exchanger (LAHX) fluidly connected to the second cooling liquid circuit and configured to cool the second air stream using the second cooling liquid.

13. The conditioning system of claim 12, wherein the second cooling component further comprises a mechanical cooling component configured to selectively cool the second air stream.

14. The conditioning system of claim 1, wherein second cooling component cools the second air stream to a lower temperature than the first cooling component cools the first air stream.

15. A method of providing cooling to a heat load, the method comprising:
directing a first air stream through a first plenum from a first inlet to a first outlet;
directing a second air stream through a second plenum from a second inlet to a second outlet, the second air stream being directed in parallel with the first air stream directed through the first plenum;
cooling the first air stream using a first cooling component arranged inside the first plenum;
cooling a first cooling liquid circulating through a liquid to air heat exchanger (LAHX) using the first air stream circulating through the LAHX, the LAHX arranged inside the first plenum and downstream the first cooling component;
cooling the second air stream using a second cooling component arranged inside the second plenum;
cooling one or more electronic components arranged inside the second plenum downstream of the second cooling component using the first cooling liquid; and
cooling the one or more electronic components using the second air stream cooled by the second cooling component.

16. The method of claim 15, further comprising recirculating the first air stream or the second air stream through a return duct by directing air exiting the first outlet or the second outlet, respectively, back to the first inlet or the second inlet, respectively.

17. The method of claim 15, further comprising mixing the first air stream and the second air stream within a return plenum connected to the first outlet and the second outlet, the first air stream and the second air stream flowing through the first outlet and the second outlet, respectively.

18. The method of claim 17, further comprising recirculating air from the return plenum back to the first inlet and the second inlet using a return duct connected to the return plenum.

19. The method of claim 15, further comprising:
selectively directing outdoor air into the first plenum using a first set of bypass dampers; and
selectively directing outdoor air into the second plenum using a second set of bypass dampers.

20. The method of claim 15, further comprising:
cooling a second cooling liquid circulating through a second cooling liquid circuit using an external liquid cooler; and
using the second cooling liquid in the second cooling liquid circuit to cool the first air stream.
